(19) United States
(12) Patent Application Publication
(10) Pub. No.: US 2022/0002490 A1
(43) Pub. Date: Jan. 6, 2022

(54) POLYIMIDE COMPONENT, POLYIMIDE FILM, AND POLYIMIDE COPPER CLAD LAMINATE

(71) Applicant: Zhen Ding Technology Co., Ltd., Tayuan (TW)

(72) Inventors: KUAN-WEI LEE, Tayuan (TW); SZU-HSIANG SU, Taoyuan (TW); SHOU-JUI HSIANG, Tayuan (TW); PEI-JUNG WU, Taoyuan (TW); WEI-HSIN HUANG, Tayuan (TW)

(21) Appl. No.: 16/990,148

(22) Filed: Aug. 11, 2020

(30) Foreign Application Priority Data
Jul. 6, 2020 (CN) 202010642449.3

(51) Int. Cl. C08G 73/10; C08J 5/18

(52) U.S. Cl. CPC C08G 73/1085; C08J 2379/08; C08J 5/18

(57) ABSTRACT

A polyimide component being transparent includes a dianhydride monomer and a diamine monomer. The dianhydride monomer has an asymmetric structure. The dianhydride monomer has at least one first polar group and at least one side chain group. The first polar group is an ester group. A molecular structural formula of the side chain group is:

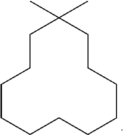

The diamine monomer has an asymmetric structure and at least one second polar group. The second polar group is at least one of a nitrogen heterocycle and an ether group. The polyimide component is polymerized by the dianhydride monomer and the diamine monomer. The disclosure also relates to a polyimide film and a polyimide copper clad laminate.

### FIELD

The subject matter of the application generally relates to polyimide component, a polyimide film, and a polyimide copper clad laminate.

### BACKGROUND

Printed circuit boards have been widely used in various electronic products. The printed circuit boards are generally made of copper clad laminates as base materials. The copper clad laminate includes a copper layer, a polyimide film, and an adhesive layer formed between the copper layer and the polyimide film.

In a manufacturing process of the printed circuit board, a part of the copper layer bonded to the polyimide film is etched away to expose the polyimide film. A camera is used to see through the polyimide film without copper layer to accurately position the component. In this way, the polyimide film without copper foil is required to have excellent light transmittance. In an installing process of the printed circuit board, the camera is used to X-ray the exposed polyimide film to accurately position components on the printed circuit board. In this way, the polyimide film without copper layer is required to have excellent light transmittance. However, the polyimide film mostly shows brown and yellow, and a structure of the polyimide film contains groups such as benzene ring (C═C), which makes the π electron conjugation effect on the conjugated benzene ring and the intermolecular and the intramolecular charge transfer complex to be generated, causing the polyimide film to absorb strongly in the visible light region, and making the polyimide film opaque.

Therefore, there is room for improvement in the art.

### BRIEF DESCRIPTION OF THE DRAWINGS

Implementations of the present disclosure will now be described, by way of exemplary embodiments, with reference to the attached FIGURES.

FIG. 1 is a cross-sectional view of an exemplary embodiment of a polyimide copper clad laminate according to the present disclosure.

### DETAILED DESCRIPTION

It will be appreciated that for simplicity and clarity of illustration, where appropriate, reference numerals have been repeated among the different FIGURES to indicate corresponding or analogous elements. In addition, numerous specific details are set forth in order to provide a thorough understanding of the exemplary embodiments described herein. However, it will be understood by those of ordinary skill in the art that the exemplary embodiments described herein can be practiced without these specific details. In other instances, methods, procedures, and components have not been described in detail so as not to obscure the related relevant feature being described. Also, the description is not to be considered as limiting the scope of the exemplary embodiments described herein. The drawings are not necessarily to scale, and the proportions of certain portions may be exaggerated to better illustrate details and features of the present disclosure.

The disclosure is illustrated by way of example and not by way of limitation in the FIGURES of the accompanying drawings, in which like references indicate similar elements. It should be noted that references to “an” or “one” exemplary embodiment in this disclosure are not necessarily to the same exemplary embodiment, and such references mean “at least one.”

The term “comprising” when utilized, means “including, but not necessarily limited to”; it specifically indicates open-ended inclusion or membership in the so-described combination, group, series, and the like.

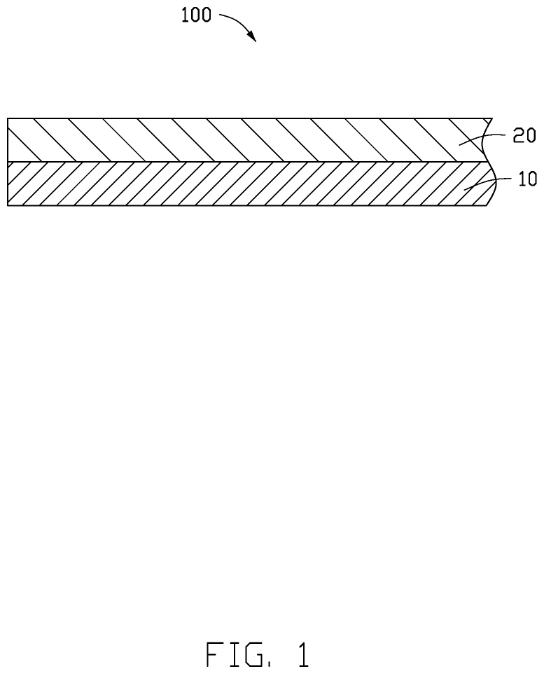

FIG. 1 shows an exemplary embodiment of a polyimide copper clad laminate 100. The polyimide copper clad laminate 100 includes a copper layer 20 and at least one polyimide film 10 formed on the copper layer 20.

The polyimide film 10 is made of polyimide component.

The polyimide component include at least one dianhydride monomer and at least one diamine monomer. The dianhydride monomer and the diamine monomer are polymerized.

The dianhydride monomer has an asymmetric structure. The dianhydride monomer has at least one first polar group and at least one side chain group. The first polar group is an ester group. A molecular structural formula of the side chain group is:

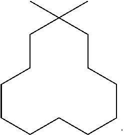

The diamine monomer has an asymmetric structure and has at least one second polar group. The second polar group is at least one of a nitrogen heterocycle and an ether group.

In at least one exemplary embodiment, the dianhydride monomer is cyclododecane-1,1-diylbis(2-methyl-4,1-phenylene)bis(1,3-dioxo-1,3-dihydroisobenzofuran-5-carboxy acid ethyl ester). The cyclododecane-1,1-diylbis(2-methyl-4,1-phenylene)bis(1,3-dioxo-1,3-dihydroisobenzofuran-5-carboxy acid ethyl ester) is abbreviated to TBIS-DMPN. A molecular structural formula of the TBIS-DMPN is:

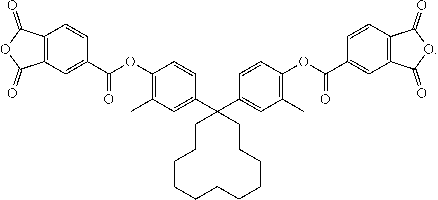 [SMILES: Cc1cc(C2(c3ccc(OC(=O)c4ccc5c(c4)C(=O)OC5=O)c(C)c3)CCCCCCCCCCC2)ccc1OC(=O)c1ccc2c(c1)C(=O)OC2=O]

In other exemplary embodiment, the dianhydride monomer may also be other dianhydride monomer having the first polar group and the side chain group.

In at least one exemplary embodiment, the diamine monomer has the nitrogen heterocycle. The diamine monomer may be selected from a group consisting of 3,5-diamino-1H-1,2,4-triazole, 4,4′-diamino-2,2′-bipyridine, 2,6-diaminopyridine, 2-(4-aminophenyl)-1H-benzimidazol-5-amine, and any combination thereof. A molecular structural formula of the 3,5-Diamino-1H-1,2,4-triazole is:

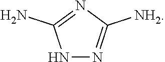

A molecular structural formula of the 4,4′-diamino-2,2′-bipyridine is:

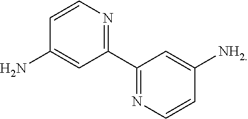 [SMILES: Nc1ccnc(-c2cc(N)ccn2)c1]

A molecular structural formula of the 2,6-diaminopyridine is:

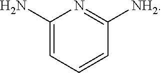

A molecular structural formula of the 2-(4-aminophenyl)-1H-benzimidazol-5-amine is:

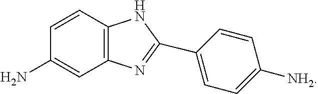 [SMILES: Nc1ccc(-c2nc3cc(N)ccc3[nH]2)cc1]

In other exemplary embodiment, the diamine monomer has the ether group, and has an asymmetric structure. The diamine monomer is 1,3-bis (3-aminophenoxy)benzene. A molecular structural formula of the 1,3-bis(3-aminophenoxy)benzene is:

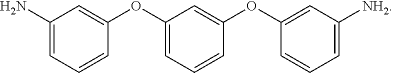 [SMILES: Nc1cccc(Oc2cccc(Oc3cccc(N)c3)c2)c1]

In other exemplary embodiment, the diamine monomer may be 2,2-bis[4-(4-aminophenoxy)phenyl]hexafluoropropane. A molecular structural formula of the 2,2-bis[4-(4-aminophenoxy)phenyl]hexafluoropropane is:

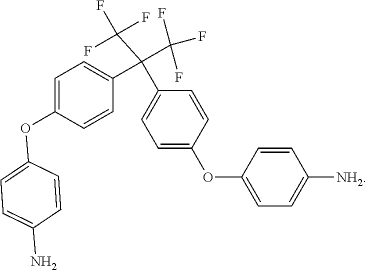 [SMILES: Nc1ccc(Oc2ccc(C(c3ccc(Oc4ccc(N)cc4)cc3)(C(F)(F)F)C(F)(F)F)cc2)cc1]

In other exemplary embodiment, the diamine monomer may also be a diamine monomer having —CF3 and having an asymmetric structure. The diamine monomer may be selected from a group consisting of 2,2′-bis(trifluoromethyl)-4,4′-diaminodiphenyl ether, 2,2-bis[4-(4-aminophenoxy)phenyl]hexafluoropropane, 2,2′-bis(trifluoromethyl)benzidine, and any combination thereof. A molecular structural formula of the 2,2′-bis(trifluoromethyl)-4,4′-diaminodiphenyl ether is:

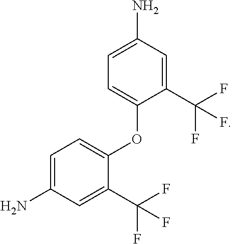 [SMILES: Nc1ccc(Oc2ccc(N)cc2C(F)(F)F)c(C(F)(F)F)c1]

A molecular structural formula of the 2,2-bis[4-(4-aminophenoxy)phenyl]hexafluoropropane is:

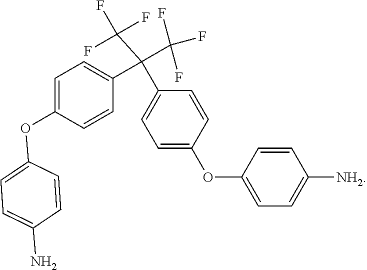 [SMILES: Nc1ccc(Oc2ccc(C(c3ccc(Oc4ccc(N)cc4)cc3)(C(F)(F)F)C(F)(F)F)cc2)cc1]

A molecular structural formula of the 2,2′-bis(trifluoromethyl)benzidine is:

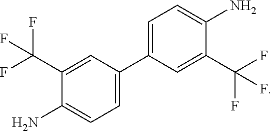 [SMILES: Nc1ccc(-c2ccc(N)c(C(F)(F)F)c2)cc1C(F)(F)F]

In other exemplary embodiment, the diamine monomer may also be a diamine monomer having —SO₂— and having an asymmetric structure. The diamine monomer is 4,4′-diaminodiphenylsulfone. A molecular structural formula of the 4,4′-diaminodiphenylsulfone is:

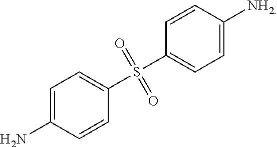 [SMILES: Nc1ccc(S(=O)(=O)c2ccc(N)cc2)cc1]

A molar ratio of the dianhydride monomer to the diamine monomer is from 0.8 to 1.2. In at least one exemplary embodiment, a molar weight of the dianhydride monomer has a range from 0.08 to 0.12 mol, and a molar weight of the diamine monomer has a range from 0.08 to 0.12 mol.

The polyimide component further include a solvent. The solvent has a weight percentage of the polyimide composition that is from 70% to 85%.

In other exemplary embodiment, the solvent is a bipolar aprotic solvent. The bipolar aprotic solvent may be selected from a group consisting of gamma-Butyrolactone (GBL), dimethylformamide (DMF), dimethylacetamide (DMAC), N-methylpyrrolidone (NMP), dimethylsulfoxide (DMSO), and any combination thereof. The amount of the solvent added can be changed as needed, as long as the diamine monomer and the dianhydride monomer can be completely dissolved.

A method for manufacturing the polyimide component includes: firstly, the dianhydride monomer, the diamine monomer, and the solvent are added into a reaction bottle. The molar ratio of the dianhydride monomer to the diamine monomer is 1:1. The solvent is GBL/NMP. The weight ratio of the GBL and the NMP is 1:1. The solid content in the reaction bottle is from 20% to 25%. Secondly, the solution in the reaction bottle is stirred for 12 hours, heated at 80 □, and then stirred for 4 hours to make the dianhydride monomer and the diamine monomer to react. Thirdly, the reaction temperature is increased to 180° C., a reflux tube is set up to connect to the reaction bottle, and xylene is added to the reflux tube. The weight of the xylene is ⅕ of the weight of the solvent GBL and NMP. The solution and the xylene in the reaction bottle are reacted for 16-18 hours to get a polyimide composition solution. The polyimide composition solution is transparent.

In at least one exemplary embodiment, the copper layer 20 is an electrolytic copper foil. A thickness of the copper layer 20 is 12 micrometers. A thickness of the polyimide film 10 is 12˜25 micrometers. The baking temperature is from 200° C. to 250° C.

The solid state of the polyimide component is polymerized by the dianhydride monomer and the diamine monomer to make the polyimide component have an asymmetric structure. The solid state of the polyimide component has the first polar group, the second polar group, and the side chain group. The first polar group, the second polar group, and the side chain group can destroy a stability of the polyimide main chain, thereby preventing the generation of intermolecular and intramolecular charge transfer complex action of the polyimide film and inhibiting the polyimide film to strongly absorb visible light, thereby making the polyimide film transparent.

A method for manufacturing the polyimide copper clad laminate 100 is provided. Firstly, a copper layer 20 is provided. The thickness of the copper layer 20 is 12 micrometers. Secondly, the polyimide component are provided and coated on the copper layer 20. Thirdly, the copper layer 20 with the polyimide component are heated to remove the solvent in the polyimide component, thereby obtaining the polyimide film 10 and the polyimide copper clad laminate 100.

The polyimide film 10 also can be formed on a release film, a resin, and other substrate.

The polyimide film 10 includes at least one first polar group, at least one side chain group, and at least one second polar group. The polyimide film 10 has an asymmetric structure. The first polar group is an ester group. A molecular structural formula of the side chain group is:

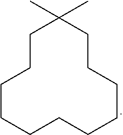

The second polar group is at least one of a nitrogen heterocycle and an ether group.

The method for manufacturing the polyimide component is further explained by specific examples and comparative examples below. The abbreviations in Comparative Examples 1-17 and their corresponding names and molecular structures are as follows:

ODA is short for 4,4′-diaminodiphenyl ether, and a molecular structural formula of the ODA is:

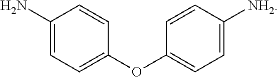 [SMILES: Nc1ccc(Oc2ccc(N)cc2)cc1]

TPE-R is short for 4,4′-(1,3-Phenylenedioxy)dianiline, and a molecular structural formula of the TPE-R is:

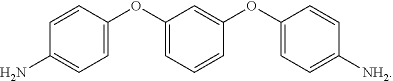 [SMILES: Nc1ccc(Oc2cccc(Oc3ccc(N)cc3)c2)cc1]

NBDA is short for bicyclo[2.2.1]heptanedimethanamine, and a molecular structural formula of the NBDA is:

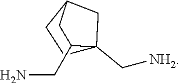 [SMILES: NCC1CC2CCC1(CN)C2]

44′DDS is short for 4,4′-diaminodiphenylsulfone, and a molecular structural formula of the 44′DDS is:

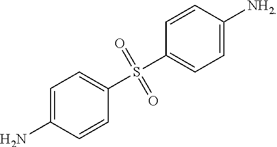 [SMILES: Nc1ccc(S(=O)(=O)c2ccc(N)cc2)cc1]

6FODA is short for 2,2′-Bis(trifluoromethyl)-4,4′-diaminodiphenyl ether, and a molecular structural formula of the 6FODA is:

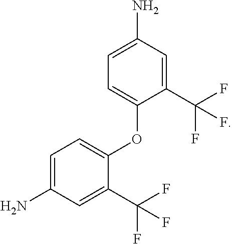 [SMILES: Nc1ccc(Oc2ccc(N)cc2C(F)(F)F)c(C(F)(F)F)c1]

BFAF is short for 9,9-Bis(4-amino-3-fluorophenyl)fluorene, and a molecular structural formula of the BFAF is:

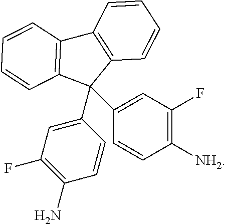 [SMILES: Nc1ccc(C2(c3ccc(N)c(F)c3)c3ccccc3-c3ccccc32)cc1F]

TFMB is short for 2,2′-bis(trifluoromethyl)benzidine, and a molecular structural formula of the TFMB is:

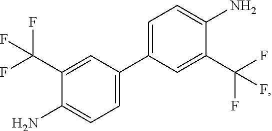 [SMILES: Nc1ccc(-c2ccc(N)c(C(F)(F)F)c2)cc1C(F)(F)F]

HFBAPP is short for 2,2-bis[4-(4-aminophenoxy)phenyl]hexafluoropropane, and a molecular structural formula of the HFBAPP is:

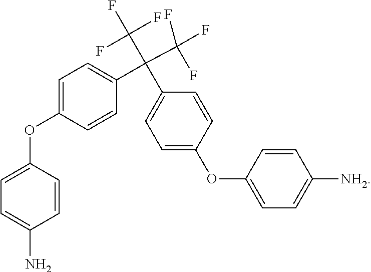 [SMILES: Nc1ccc(Oc2ccc(C(c3ccc(Oc4ccc(N)cc4)cc3)(C(F)(F)F)C(F)(F)F)cc2)cc1]

TAHQ is short for 2p-phenylenebis(trimellitate anhydride), and a molecular structural formula of the TAHQ is:

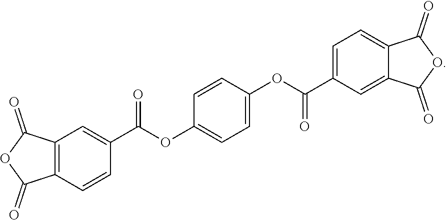 [SMILES: O=C(Oc1ccc(OC(=O)c2ccc3c(c2)C(=O)OC3=O)cc1)c1ccc2c(c1)C(=O)OC2=O]

HPMDA is short for 1,2,4,5-Cyclohexanetetracarboxylic dianhydride, and a molecular structural formula of the HPMDA is:

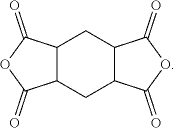 [SMILES: O=C1OC(=O)C2CC3C(=O)OC(=O)C3CC12]

PMDA is short for 1,2,4,5-Benzenetetracarboxylic anhydride, and a molecular structural formula of the PMDA is:

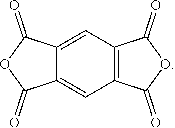 [SMILES: O=c1oc(=O)c2cc3c(=O)oc(=O)c3cc12]

6FDA is short for 4,4′-(hexafluoroisopropylidene)diphthalic anhydride, and a molecular structural formula of the 6FDA is:

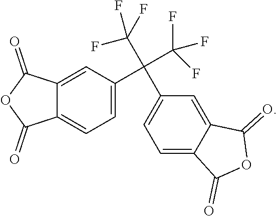 [SMILES: O=C1OC(=O)c2cc(C(c3ccc4c(c3)C(=O)OC4=O)(C(F)(F)F)C(F)(F)F)ccc21]

### Example 1

Firstly, DTZ (0.1 mol, 9.91 g) and GBL/NMP (1:1, 248.36 g) are added into a reaction bottle and stirred on a high speed until the DTZ is dissolved in the GBL/NMP. Secondly, TBIS-DMPN (0.1 mol, 72.88 g) is added into the reaction bottle, stirred for 12 hours, heated to 80° C., and stirred until the TBIS-DMPN is dissolved in the GBL/NMP. A solid fraction of the solution in the reaction bottle is 20-25% by mass. In the process of stirring until the TBIS-DMPN is dissolved in the GBL/NMP, xylene (49.67 g) is added into the reaction bottle, and the temperature in the reaction bottle is heated to 180° C., and a return pipe is set up and connected to the reaction bottle. The transparent polyimide component solution is prepared at 180° C. for 16-18 hours.

### Example 2

Firstly, 4,4′-diamino-2,2′-bipyridine (0.1 mol, 18.62 g) and GBL/NMP (1:1, 274.5 g) are added into a reaction bottle and stirred on a high speed until the 4,4′-diamino-2,2′-bipyridine is dissolved in the GBL/NMP. Secondly, TBIS-DMPN (0.1 mol, 72.88 g) is added into the reaction bottle, stirred for 12 hours, heated to 80° C., and stirred until the TBIS-DMPN is dissolved in the GBL/NMP. A solid fraction of the solution in the reaction bottle is 20-25% by mass. In the process of stirring until the TBIS-DMPN is dissolved in the GBL/NMP, xylene (54.9 g) is added into the reaction bottle, and the temperature in the reaction bottle is heated to 180° C., and a return pipe is set up and connected to the reaction bottle. The transparent polyimide component solution is prepared at 180° C. for 16-18 hours.

### Example 3

Firstly, APB-N (0.1 mol, 29.23 g) and GBL/NMP (1:1, 306.34 g) are added into a reaction bottle and stirred on a high speed until the APB-N is dissolved in the GBL/NMP. Secondly, TBIS-DMPN (0.1 mol, 72.88 g) is added into the reaction bottle, stirred for 12 hours, heated to 80° C., and stirred until the TBIS-DMPN is dissolved in the GBL/NMP. A solid fraction of the solution in the reaction bottle is 20-25% by mass. In the process of stirring until the TBIS-DMPN is dissolved in the GBL/NMP, xylene (61.27 g) is added into the reaction bottle, and the temperature in the reaction bottle is heated to 180° C., and a return pipe is set up and connected to the reaction bottle. The transparent polyimide component solution is prepared at 180° C. for 16-18 hours.

### Comparative Example 1

Firstly, DTZ (0.1 mol, 9.91 g) and GBL/NMP (1:1, 167.23 g) are added into a reaction bottle and stirred on a high speed until the DTZ is dissolved in the GBL/NMP. Secondly, TAHQ (0.1 mol, 45.83 g) is added into the reaction bottle, stirred for 12 hours, heated to 80° C., and stirred until the TAHQ is dissolved in the GBL/NMP. A solid fraction of the solution in the reaction bottle is 20-25% by mass. In the process of stirring until the TAHQ is dissolved in the GBL/NMP, xylene (33.44 g) is added into the reaction bottle, and the temperature in the reaction bottle is heated to 180° C., and a return pipe is set up and connected to the reaction bottle. The transparent polyimide component solution is prepared at 180° C. for 16-18 hours.

### Comparative Example 2

Firstly, 4,4′-diamino-2,2′-bipyridine (0.1 mol, 18.62 g) and GBL/NMP (1:1, 193.37 g) are added into a reaction bottle and stirred on a high speed until the 4,4′-diamino-2,2′-bipyridine is dissolved in the GBL/NMP. Secondly, TAHQ (0.1 mol, 45.83 g) is added into the reaction bottle, stirred for 12 hours, heated to 80° C., and stirred until the TAHQ is dissolved in the GBL/NMP. A solid fraction of the solution in the reaction bottle is 20-25% by mass. In the process of stirring until the TAHQ is dissolved in the GBL/NMP, xylene (38.67 g) is added into the reaction bottle, and the temperature in the reaction bottle is heated to 180° C., and a return pipe is set up and connected to the reaction bottle. The transparent polyimide component solution is prepared at 180° C. for 16-18 hours.

### Comparative Example 3

Firstly, APB-N (0.1 mol, 29.23 g) and GBL/NMP (1:1, 225.2 g) are added into a reaction bottle and stirred on a high speed until the APB-N is dissolved in the GBL/NMP. Secondly, TAHQ (0.1 mol, 45.83 g) is added into the reaction bottle, stirred for 12 hours, heated to 80° C., and stirred until the TAHQ is dissolved in the GBL/NMP. A solid fraction of the solution in the reaction bottle is 20-25% by mass. In the process of stirring until the TAHQ is dissolved in the GBL/NMP, xylene (45.04 g) is added into the reaction bottle, and the temperature in the reaction bottle is heated to 180° C., and a return pipe is set up and connected to the reaction bottle. The transparent polyimide component solution is prepared at 180° C. for 16-18 hours.

### Comparative Example 4

Firstly, DTZ (0.1 mol, 9.91 g) and GBL/NMP (1:1, 163.00 g) are added into a reaction bottle and stirred on a high speed until the DTZ is dissolved in the GBL/NMP. Secondly, 6FDA (0.1 mol, 44.42 g) is added into the reaction bottle, stirred for 12 hours, heated to 80° C., and stirred until the 6FDA is dissolved in the GBL/NMP. A solid fraction of the solution in the reaction bottle is 20-25% by mass. In the process of stirring until the 6FDA is dissolved in the GBL/NMP, xylene (32.06 g) is added into the reaction bottle, and the temperature in the reaction bottle is heated to 180° C., and a return pipe is set up and connected to the reaction bottle. The transparent polyimide component solution is prepared at 180° C. for 16-18 hours.

### Comparative Example 5

Firstly, 4,4′-diamino-2,2′-bipyridine (0.1 mol, 18.62 g) and GBL/NMP (1:1, 189.14 g) are added into a reaction bottle and stirred on a high speed until the 4,4′-diamino-2,2′-bipyridine is dissolved in the GBL/NMP. Secondly, 6FDA (0.1 mol, 44.42 g) is added into the reaction bottle, stirred for 12 hours, heated to 80° C., and stirred until the 6FDA is dissolved in the GBL/NMP. A solid fraction of the solution in the reaction bottle is 20-25% by mass. In the process of stirring until the 6FDA is dissolved in the GBL/NMP, xylene (37.82 g) is added into the reaction bottle, and the temperature in the reaction bottle is heated to 180° C., and a return pipe is set up and connected to the reaction bottle. The transparent polyimide component solution is prepared at 180° C. for 16-18 hours.

### Comparative Example 6

Firstly, APB-N (0.1 mol, 29.23 g) and GBL/NMP (1:1, 220.97 g) are added into a reaction bottle and stirred on a high speed until the APB-N is dissolved in the GBL/NMP. Secondly, 6FDA (0.1 mol, 44.42 g) is added into the reaction bottle, stirred for 12 hours, heated to 80° C., and stirred until the 6FDA is dissolved in the GBL/NMP. A solid fraction of the solution in the reaction bottle is 20-25% by mass. In the process of stirring until the 6FDA is dissolved in the GBL/NMP, xylene (44.19 g) is added into the reaction bottle, and the temperature in the reaction bottle is heated to 180° C., and a return pipe is set up and connected to the reaction bottle. The transparent polyimide component solution is prepared at 180° C. for 16-18 hours.

### Comparative Example 7

Firstly, DTZ (0.1 mol, 9.91 g) and GBL/NMP (1:1, 96.98 g) are added into a reaction bottle and stirred on a high speed until the DTZ is dissolved in the GBL/NMP. Secondly, HPMDA (0.1 mol, 22.42 g) is added into the reaction bottle, stirred for 12 hours, heated to 80° C., and stirred until the HPMDA is dissolved in the GBL/NMP. A solid fraction of the solution in the reaction bottle is 20-25% by mass. In the process of stirring until the HPMDA is dissolved in the GBL/NMP, xylene (19.39 g) is added into the reaction bottle, and the temperature in the reaction bottle is heated to 180° C., and a return pipe is set up and connected to the reaction bottle. The transparent polyimide component solution is prepared at 180° C. for 16-18 hours.

### Comparative Example 8

Firstly, 4,4′-diamino-2,2′-bipyridine (0.1 mol, 18.62 g) and GBL/NMP (1:1, 123.12 g) are added into a reaction bottle and stirred on a high speed until the 4,4′-diamino-2,2′-bipyridine is dissolved in the GBL/NMP. Secondly, HPMDA (0.1 mol, 22.42 g) is added into the reaction bottle, stirred for 12 hours, heated to 80° C., and stirred until the HPMDA is dissolved in the GBL/NMP. A solid fraction of the solution in the reaction bottle is 20-25% by mass. In the process of stirring until the HPMDA is dissolved in the GBL/NMP, xylene (24.62 g) is added into the reaction bottle, and the temperature in the reaction bottle is heated to 180° C., and a return pipe is set up and connected to the reaction bottle. The transparent polyimide component solution is prepared at 180° C. for 16-18 hours.

### Comparative Example 9

Firstly, APB-N (0.1 mol, 29.23 g) and GBL/NMP (1:1, 154.95 g) are added into a reaction bottle and stirred on a high speed until the APB-N is dissolved in the GBL/NMP. Secondly, HPMDA (0.1 mol, 22.42 g) is added into the reaction bottle, stirred for 12 hours, heated to 80° C., and stirred until the HPMDA is dissolved in the GBL/NMP. A solid fraction of the solution in the reaction bottle is 20-25% by mass. In the process of stirring until the HPMDA is dissolved in the GBL/NMP, xylene (30.99 g) is added into the reaction bottle, and the temperature in the reaction bottle is heated to 180° C., and a return pipe is set up and connected to the reaction bottle. The transparent polyimide component solution is prepared at 180° C. for 16-18 hours.

### Comparative Example 10

Firstly, ODA (0.1 mol, 20.02 g) and GBL/NMP (1:1, 278.71 g) are added into a reaction bottle and stirred on a high speed until the ODA is dissolved in the GBL/NMP. Secondly, TBIS-DMPN (0.1 mol, 72.88 g) is added into the reaction bottle, stirred for 12 hours, heated to 80° C., and stirred until the TBIS-DMPN is dissolved in the GBL/NMP. A solid fraction of the solution in the reaction bottle is 20-25% by mass. In the process of stirring until the TBIS-DMPN is dissolved in the GBL/NMP, xylene (55.74 g) is added into the reaction bottle, and the temperature in the reaction bottle is heated to 180° C., and a return pipe is set up and connected to the reaction bottle. The transparent polyimide component solution is prepared at 180° C. for 16-18 hours.

### Comparative Example 11

Firstly, TPE-R (0.1 mol, 29.23 g) and GBL/NMP (1:1, 306.33 g) are added into a reaction bottle and stirred on a high speed until the TPE-R is dissolved in the GBL/NMP. Secondly, TBIS-DMPN (0.1 mol, 72.88 g) is added into the reaction bottle, stirred for 12 hours, heated to 80° C., and stirred until the TBIS-DMPN is dissolved in the GBL/NMP. A solid fraction of the solution in the reaction bottle is 20-25% by mass. In the process of stirring until the TBIS-DMPN is dissolved in the GBL/NMP, xylene (61.27 g) is added into the reaction bottle, and the temperature in the reaction bottle is heated to 180° C., and a return pipe is set up and connected to the reaction bottle. The transparent polyimide component solution is prepared at 180° C. for 16-18 hours.

### Comparative Example 12

Firstly, NBDA (0.1 mol, 15.43 g) and GBL/NMP (1:1, 264.91 g) are added into a reaction bottle and stirred on a high speed until the NBDA is dissolved in the GBL/NMP. Secondly, TBIS-DMPN (0.1 mol, 72.88 g) is added into the reaction bottle, stirred for 12 hours, heated to 80° C., and stirred until the TBIS-DMPN is dissolved in the GBL/NMP. A solid fraction of the solution in the reaction bottle is 20-25% by mass. In the process of stirring until the TBIS-DMPN is dissolved in the GBL/NMP, xylene (52.98 g) is added into the reaction bottle, and the temperature in the reaction bottle is heated to 180° C., and a return pipe is set up and connected to the reaction bottle. The transparent polyimide component solution is prepared at 180° C. for 16-18 hours.

### Comparative Example 13

Firstly, 44′DDS (0.1 mol, 24.83 g) and GBL/NMP (1:1, 293.12 g) are added into a reaction bottle and stirred on a high speed until the 44′DDS is dissolved in the GBL/NMP. Secondly, TBIS-DMPN (0.1 mol, 72.88 g) is added into the reaction bottle, stirred for 12 hours, heated to 80° C., and stirred until the TBIS-DMPN is dissolved in the GBL/NMP. A solid fraction of the solution in the reaction bottle is 20-25% by mass. In the process of stirring until the TBIS-DMPN is dissolved in the GBL/NMP, xylene (58.62 g) is added into the reaction bottle, and the temperature in the reaction bottle is heated to 180° C., and a return pipe is set up and connected to the reaction bottle. The transparent polyimide component solution is prepared at 180° C. for 16-18 hours.

### Comparative Example 14

Firstly, 6FODA (0.1 mol, 33.62 g) and GBL/NMP (1:1, 319.50 g) are added into a reaction bottle and stirred on a high speed until the 6FODA is dissolved in the GBL/NMP. Secondly, TBIS-DMPN (0.1 mol, 72.88 g) is added into the reaction bottle, stirred for 12 hours, heated to 80° C., and stirred until the TBIS-DMPN is dissolved in the GBL/NMP. A solid fraction of the solution in the reaction bottle is 20-25% by mass. In the process of stirring until the TBIS-DMPN is dissolved in the GBL/NMP, xylene (63.90 g) is added into the reaction bottle, and the temperature in the reaction bottle is heated to 180° C., and a return pipe is set up and connected to the reaction bottle. The transparent polyimide component solution is prepared at 180° C. for 16-18 hours.

### Comparative Example 15

Firstly, TFMB (0.1 mol, 32.02 g) and GBL/NMP (1:1, 314.70 g) are added into a reaction bottle and stirred on a high speed until the TFMB is dissolved in the GBL/NMP. Secondly, TBIS-DMPN (0.1 mol, 72.88 g) is added into the reaction bottle, stirred for 12 hours, heated to 80° C., and stirred until the TBIS-DMPN is dissolved in the GBL/NMP. A solid fraction of the solution in the reaction bottle is 20-25% by mass. In the process of stirring until the TBIS-DMPN is dissolved in the GBL/NMP, xylene (62.94 g) is added into the reaction bottle, and the temperature in the reaction bottle is heated to 180° C., and a return pipe is set up and connected to the reaction bottle. The transparent polyimide component solution is prepared at 180° C. for 16-18 hours.

### Comparative Example 16

Firstly, BFAF (0.1 mol, 38.44 g) and GBL/NMP (1:1, 333.96 g) are added into a reaction bottle and stirred on a high speed until the BFAF is dissolved in the GBL/NMP. Secondly, TBIS-DMPN (0.1 mol, 72.88 g) is added into the reaction bottle, stirred for 12 hours, heated to 80° C., and stirred until the TBIS-DMPN is dissolved in the GBL/NMP. A solid fraction of the solution in the reaction bottle is 20-25% by mass. In the process of stirring until the TBIS-DMPN is dissolved in the GBL/NMP, xylene (66.79 g) is added into the reaction bottle, and the temperature in the reaction bottle is heated to 180° C., and a return pipe is set up and connected to the reaction bottle. The transparent polyimide component solution is prepared at 180° C. for 16-18 hours.

### Comparative Example 17

Firstly, HFBAPP (0.1 mol, 51.85 g) and GBL/NMP (1:1, 374.18 g) are added into a reaction bottle and stirred on a high speed until the HFBAPP is dissolved in the GBL/NMP. Secondly, TBIS-DMPN (0.1 mol, 72.88 g) is added into the reaction bottle, stirred for 12 hours, heated to 80° C., and stirred until the TBIS-DMPN is dissolved in the GBL/NMP. A solid fraction of the solution in the reaction bottle is 20-25% by mass. In the process of stirring until the TBIS-DMPN is dissolved in the GBL/NMP, xylene (74.83 g) is added into the reaction bottle, and the temperature in the reaction bottle is heated to 180° C., and a return pipe is set up and connected to the reaction bottle. The transparent polyimide component solution is prepared at 180° C. for 16-18 hours.

The transparent polyimide component solutions made in Examples 1-3 and Comparative Examples 1-17 are coated on the copper layers 20, respectively. The copper layers 20 with the transparent polyimide component solutions are heated to obtain the polyimide copper clad laminates 100. The polyimide copper clad laminates 100 are respectively tested for penetrability, copper peel strength, and tin drift. The test results are shown in Table 1 and Table 2. In the tin bleaching test, if the tin bleaching test lasts for 30 sec at 288° C. and the polyimide film 10 does not change color or bubble, the tin bleaching test result is “passed”, indicating that the polyimide copper clad laminate 100 meets the requirements of the tin bleaching test.

TABLE 1

| | | | | | | Com- | Com- | Com- | Com- | Com- | Com- | Com- |
|---|---|---|---|---|---|---|---|---|---|---|---|---|
| | | | | | | para- | para- | para- | para- | para- | para- | para- |
| | | | | | | tive | tive | tive | tive | tive | tive | tive |
| | | Model/ | Exam- | Exam- | Exam- | exam- | exam- | exam- | exam- | exam- | exam- | exam- |
| | | standard | ple 1 | ple 2 | ple 3 | ple 1 | ple 2 | ple 3 | ple 4 | ple 5 | ple 6 | ple 7 |
| polyimide | dian- | TBIS-DMPN | 0.1 | 0.1 | 0.1 | | | | | | | |
| component | hydride | TAHQ | | | | 0.1 | 0.1 | 0.1 | | | | |
| | | 6FDA | | | | | | | 0.1 | 0.1 | 0.1 | |
| | | HPMDA | | | | | | | | | | 0.1 |
| | di- | DTZ | 0.1 | | | 0.1 | | | 0.1 | | | 0.1 |
| | amine | 4,4′- | | 0.1 | | | 0.1 | | | 0.1 | | |
| | | diamino- | | | | | | | | | | |
| | | 2,2′- | | | | | | | | | | |
| | | bipyridine | | | | | | | | | | |
| | | APB-N | | | 0.1 | | | 0.1 | | | 0.1 | |

| solvent | NMP | 50 | 50 | 50 | 50 | 50 | 50 | 50 | 50 | 50 | 50 |
|---|---|---|---|---|---|---|---|---|---|---|---|
| | GBL | 50 | 50 | 50 | 50 | 50 | 50 | 50 | 50 | 50 | 50 |
| penetrability | 550 nm | 92 | 94 | 91 | 65 | 66 | 62 | 73 | 73 | 70 | 78 |
| T % | | | | | | | | | | | |
| Cu peel strength | IPC-TM650 | 1.2 | 0.93 | 0.91 | 0.8 | 0.73 | 0.75 | 0.65 | 0.65 | 0.53 | 0.75 |
| (Kgf/cm) | 2.4.9 | | | | | | | | | | |
| tin drift | IPC- | PASS | PASS | PASS | PASS | PASS | PASS | PASS | PASS | PASS | NG |
| 288^{°} C./30 s | TM6502.4.13 | | | | | | | | | | |

TABLE 2

| | | | Com- | Com- | Com- | Com- | Com- | Com- | Com- | Com- | Com- | Com- |
|---|---|---|---|---|---|---|---|---|---|---|---|---|
| | | | para- | para- | para- | para- | para- | para- | para- | para- | para- | para- |
| | | | tive | tive | tive | tive | tive | tive | tive | tive | tive | tive |
| | | Model/ | exam- | exam- | exam- | exam- | exam- | exam- | exam- | exam- | exam- | exam- |
| | | standard | ple 8 | ple 9 | ple 10 | ple 11 | ple 12 | ple 13 | ple 14 | ple 15 | ple 16 | ple 17 |
| polyimide | dian- | TBIS-DMPN | | | 0.1 | 0.1 | 0.1 | 0.1 | 0.1 | 0.1 | 0.1 | 0.1 |
| component | hydride | HPMDA | 0.1 | 0.1 | | | | | | | | |
| | di- | 4,4′- | 0.1 | | | | | | | | | |
| | amine | diamino- | | | | | | | | | | |
| | | 2,2′- | | | | | | | | | | |
| | | bipyridine | | | | | | | | | | |
| | | APB-N | | 0.1 | | | | | | | | |
| | | ODA | | | 0.1 | | | | | | | |
| | | TPE-R | | | | 0.1 | | | | | | |
| | | NBDA | | | | | 0.1 | | | | | |
| | | 44′DDS | | | | | | 0.1 | | | | |
| | | 6FODA | | | | | | | 0.1 | | | |
| | | TFMB | | | | | | | | 0.1 | | |
| | | BFAF | | | | | | | | | 0.1 | |
| | | HFBAPP | | | | | | | | | | 0.1 |

| solvent | NMP | 50 | 50 | 50 | 50 | 50 | 50 | 50 | 50 | 50 | 50 |
|---|---|---|---|---|---|---|---|---|---|---|---|
| | GBL | 50 | 50 | 50 | 50 | 50 | 50 | 50 | 50 | 50 | 50 |
| penetrability | 550 nm | 80 | 74 | 85 | 83 | 79 | 80 | 88 | 80 | 83 | 90 |
| T % | | | | | | | | | | | |
| Cu peel strength | IPC-TM650 | 0.79 | 0.69 | 0.87 | 0.81 | 0.88 | 0.82 | 0.69 | 0.52 | 0.54 | 0.74 |
| (Kgf/cm) | 2.4.9 | | | | | | | | | | |
| tin drift | IPC- | NG | NG | PASS | PASS | NG | PASS | PASS | PASS | PASS | PASS |
| 288^{°} C./30 s | TM6502.4.13 | | | | | | | | | | |

As can be seen from Table 1 and Table 2, the polyimide component of Examples 1 to 3 are polymerized of the dianhydride monomers (TBIS-DMPN) with bulky side chain groups and the diamine monomer with polar groups (nitrogen heterocycles or ether groups) and have an asymmetric structure, which can reduce the degree of charge transfer between the molecules and within the molecule, the polyimide films of Examples 1 to 3 have a good light transmittance (>88% (550 nm)), a good copper peel strength (>0.8 Kgf/cm), and a good heat resistance (288° C./30 s, PASS).

From Examples 1 to 3 and Comparative Examples 10-16, TBIS-DMPN (the dianhydride monomer) is matched with different diamine monomers, and the diamine monomers in Comparative Examples 10-16 have polar groups (—CF₃, —O—, —SO₂—), no benzene ring or bulky side chain groups (—CF₃, benzene ring), their light transmittances are less than 88% (550 nm). While in Comparative Example 14 and Comparative Example 17, the diamine monomer with polar groups (—O—) and bulky side chain groups (—CF₃), the light transmittances of the polyimide films are close to and greater than 88% (550 nm), but —CF₃ makes the polyimide film has an insufficient copper peel strength (<0.8 Kgf/cm). In Comparative Examples 4 to 6, the polyimide component use 6FDA (diacid anhydride) and the same diamine monomers as in Examples 1 to 3, because 6FDA is a fluorine group-containing monomer, which make the polyimide film has an insufficient copper peel strength. The diamine monomers APB-N in Example 3, ODA in Comparative Example 9, and TPE-R in Comparative Example 10 all have polarity group (—O—), while APB-N has one more —O— than ODA, and the APB-N has a asymmetric structure, and the TPE-R has a symmetrical structure. Compared with the symmetrical structure, the asymmetric structure has a better effect for hindering arrangements of molecules, thereby reducing the charge transfer within and between molecules to make the light transmittance be better.

In Comparative Examples 1-3, the dianhydride monomer is TAHQ and the diamine monomer is the same as the diamine monomer in Examples 1 to 3. TAHQ and TBIS-DMPN both have ester groups, which can reduce intramolecular charge transfer. But TAHQ has no bulky side chain groups, which makes it is easy to arrange between molecules, so that charge transfer occurs between molecules, which will make the transparency be less than 88% (550 nm).

In Comparative Examples 7-9, the dianhydride monomer is HPMDA and the diamine monomer is the same as the diamine monomer in Examples 1 to 3. Because HPMDA is a benzene-free monomer, the degree of intramolecular charge transfer is reduced. Because HPMDA has no side chain groups, so, the HPMDA cannot prevent the intermolecular charge transfer complexes from being generated, so that the transparency of the polyimide film be less than 88% (550 nm). Because HPMDA is aliphatic, so the heat resistance of the polyimide film is obviously insufficient (288° C./30 s, NG).

The polyimide film provided by the present disclosure has polar groups and a side chain group, the polar groups may be at least one of nitrogen heterocycle, ester group, ether group, and the like, the molecular structural formula of the side chain group is:

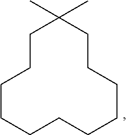

and the polyimide film is an asymmetric structure, which can destroy the stability of the main chain of the polyimide, thereby preventing the intermolecular and intramolecular charge transfer complex action of the polyimide film, inhibiting the polyimide film to strongly absorb the visible light, thereby making the polyimide film to be transparent.

The exemplary embodiments shown and described above are only examples. Many details are often found in the art such as the other features of polyimide component, a polyimide film, and a polyimide copper clad laminate. Therefore, many such details are neither shown nor described. Even though numerous characteristics and advantages of the present disclosure have been positioned forth in the foregoing description, together with details of the structure and function of the present disclosure, the disclosure is illustrative only, and changes can be made in the detail, including in matters of shape, size, and arrangement of the parts within the principles of the present disclosure, up to and including the full extent established by the broad general meaning of the terms used in the claims. It will therefore be appreciated that the exemplary embodiments described above can be modified within the scope of the claims.

What is claimed is:

1. A polyimide component comprising:
a dianhydride monomer; wherein the dianhydride monomer has an asymmetric structure; the dianhydride monomer comprises at least one first polar group and at least one side chain group; the first polar group is an ester group; and a molecular structural formula of the side chain group is: 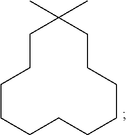
and
a diamine monomer, wherein the diamine monomer has an asymmetric structure and comprises at least one second polar group; the second polar group is at least one of a nitrogen heterocycle and an ether group; and the polyimide component is polymerized by the dianhydride monomer and the diamine monomer.

2. The polyimide component of claim 1, wherein the dianhydride monomer is cyclododecane-1,1-diylbis(2-methyl-4,1-phenylene)bis(1,3-dioxo-1,3-dihydroisobenzofuran-5-carboxy acid ethyl ester), and a molecular structural formula of the cyclododecane-1,1-diylbis(2-methyl-4,1-phenylene)bis(1,3-dioxo-1,3-dihydroisobenzofuran-5-carboxy acid ethyl ester) is:

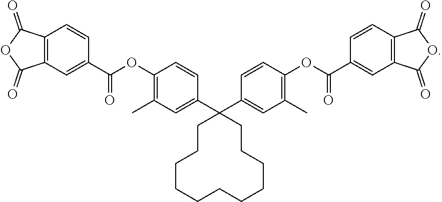 [SMILES: Cc1cc(C2(c3ccc(OC(=O)c4ccc5c(c4)C(=O)OC5=O)c(C)c3)CCCCCCCCCCC2)ccc1OC(=O)c1ccc2c(c1)C(=O)OC2=O]

3. The polyimide component of claim 1, wherein the diamine monomer is selected from a group consisting of 3,5-diamino-1H-1,2,4-triazole, 4,4′-diamino-2,2′-bipyridine, 2,6-diaminopyridine, 2-(4-aminophenyl)-1H-benzimidazol-5-amine, and 1,3-bis (3-aminophenoxy)benzene; a molecular structural formula of the 3,5-Diamino-1H-1,2,4-triazole is: 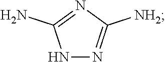
a molecular structural formula of the 4,4′-diamino-2,2′-bipyridine is: 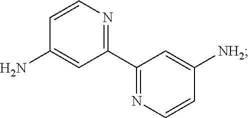 [SMILES: Nc1ccnc(-c2cc(N)ccn2)c1]
a molecular structural formula of the 2,6-diaminopyridine is: 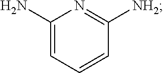
a molecular structural formula of the 2-(4-aminophenyl)-1H-benzimidazol-5-amine is: 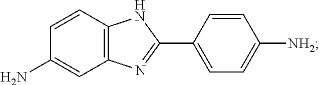 [SMILES: Nc1ccc(-c2nc3cc(N)ccc3[nH]2)cc1]
and a molecular structural formula of the 1,3-bis(3-aminophenoxy)benzene is:

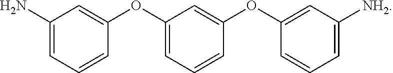 [SMILES: Nc1cccc(Oc2cccc(Oc3cccc(N)c3)c2)c1]

4. The polyimide component of claim 1, wherein a molar ratio of the dianhydride monomer to the diamine monomer is from 0.8 to 1.2.

5. The polyimide component of claim 4, wherein a molar weight of the dianhydride monomer has a range from 0.08 to 0.12 mol, and a molar weight of the diamine monomer has a range from 0.08 to 0.12 mol.

6. The polyimide component of claim 1, further comprising a solvent, wherein the solvent has a weight percentage of the polyimide component that is from 70% to 85%.

7. The polyimide component of claim 6, wherein the solvent is selected from a group consisting of dimethylformamide, dimethylacetamide, N-methylpyrrolidone, and dimethylsulfoxide.

8. A polyimide film having an asymmetric structure, comprising:
at least one first polar group; wherein the first polar group is an ester group;
at least one side chain group; wherein a molecular structural formula of the side chain group is: 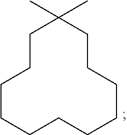
and
at least one second polar group; wherein the second polar group is at least one of a nitrogen heterocycle and an ether group.

9. The polyimide film of claim 8, wherein the polyimide film is formed by heated polyimide component coated on a substrate; the polyimide component is polymerized by a dianhydride monomer and a diamine monomer; the dianhydride monomer has an asymmetric structure; the dianhydride monomer comprises the at least one first polar group and the at least one side chain group; the first polar group is the ester group; and the molecular structural formula of the side chain group is: 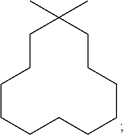
the diamine monomer has an asymmetric structure and comprises the at least one second polar group; and the second polar group is at least one of the nitrogen heterocycle and the ether group.

10. The polyimide film of claim 9, wherein the dianhydride monomer is cyclododecane-1,1-diylbis(2-methyl-4,1-phenylene)bis(1,3-dioxo-1,3-dihydroisobenzofuran-5-carboxy acid ethyl ester), and a molecular structural formula of the cyclododecane-1,1-diylbis(2-methyl-4,1-phenylene)bis(1,3-dioxo-1,3-dihydroisobenzofuran-5-carboxy acid ethyl ester) is:

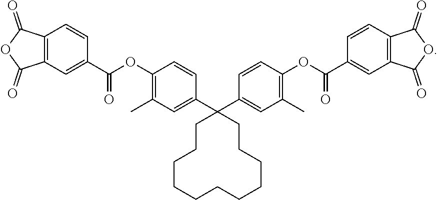 [SMILES: Cc1cc(C2(c3ccc(OC(=O)c4ccc5c(c4)C(=O)OC5=O)c(C)c3)CCCCCCCCCCC2)ccc1OC(=O)c1ccc2c(c1)C(=O)OC2=O]

11. The polyimide film of claim 9, wherein the diamine monomer is selected from a group consisting of 3,5-diamino-1H-1,2,4-triazole, 4,4′-diamino-2,2′-bipyridine, 2,6-diaminopyridine, 2-(4-aminophenyl)-1H-benzimidazol-5-amine, and 1,3-bis (3-aminophenoxy)benzene; a molecular structural formula of the 3,5-Diamino-1H-1,2,4-triazole is: 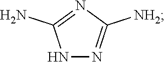
a molecular structural formula of the 4,4′-diamino-2,2′-bipyridine is: 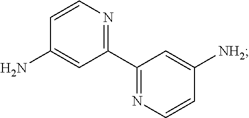 [SMILES: Nc1ccnc(-c2cc(N)ccn2)c1]
a molecular structural formula of the 2,6-diaminopyridine is: 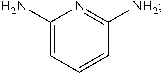
a molecular structural formula of the 2-(4-aminophenyl)-1H-benzimidazol-5-amine is: 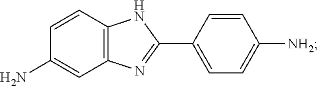 [SMILES: Nc1ccc(-c2nc3cc(N)ccc3[nH]2)cc1]
and a molecular structural formula of the 1,3-bis(3-aminophenoxy)benzene is:

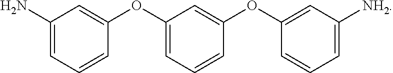 [SMILES: Nc1cccc(Oc2cccc(Oc3cccc(N)c3)c2)c1]

12. The polyimide film of claim 9, wherein a molar ratio of the dianhydride monomer to the diamine monomer is from 0.8 to 1.2.

13. The polyimide film of claim 12, wherein a molar weight of the dianhydride monomer has a range from 0.08 to 0.12 mol, and a molar weight of the diamine monomer has a range from 0.08 to 0.12 mol.

14. The polyimide film of claim 9, further comprising a solvent, and the solvent has a weight percentage of the polyimide component that is from 70% to 85%.

15. A polyimide copper clad laminate comprising:
a copper layer;
a polyimide film coated on the copper layer; wherein the polyimide film has an asymmetric structure and comprises:
at least one first polar group; wherein the first polar group is an ester group;
at least one side chain group; wherein a molecular structural formula of the side chain group is: 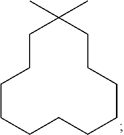
and
at least one second polar group; wherein the second polar group is at least one of a nitrogen heterocycle and an ether group.

16. The polyimide copper clad laminate of claim 15, wherein the polyimide film is formed by heated polyimide component coated on a substrate; the polyimide component is polymerized by a dianhydride monomer and a diamine monomer; the dianhydride monomer has an asymmetric structure; the dianhydride monomer comprises the at least one first polar group and the at least one side chain group; the first polar group is the ester group; and the molecular structural formula of the side chain group is: 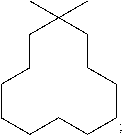
the diamine monomer has an asymmetric structure and comprises the at least one second polar group; and the second polar group is at least one of the nitrogen heterocycle and the ether group.

17. The polyimide copper clad laminate of claim 16, wherein the dianhydride monomer is cyclododecane-1,1-diylbis(2-methyl-4,1-phenylene)bis(1,3-dioxo-1,3-dihydroisobenzofuran-5-carboxy acid ethyl ester), and a molecular structural formula of the cyclododecane-1,1-diylbis(2-methyl-4,1-phenylene)bis(1,3-dioxo-1,3-dihydroisobenzofuran-5-carboxy acid ethyl ester) is:

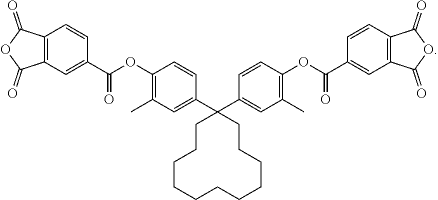 [SMILES: Cc1cc(C2(c3ccc(OC(=O)c4ccc5c(c4)C(=O)OC5=O)c(C)c3)CCCCCCCCCCC2)ccc1OC(=O)c1ccc2c(c1)C(=O)OC2=O]

18. The polyimide copper clad laminate of claim 16, wherein the diamine monomer is selected from a group consisting of 3,5-diamino-1H-1,2,4-triazole, 4,4′-diamino-2,2′-bipyridine, 2,6-diaminopyridine, 2-(4-aminophenyl)-1H-benzimidazol-5-amine, and 1,3-bis (3-aminophenoxy)benzene; a molecular structural formula of the 3,5-Diamino-1H-1,2,4-triazole is: 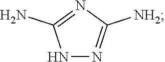
a molecular structural formula of the 4,4′-diamino-2,2′-bipyridine is: 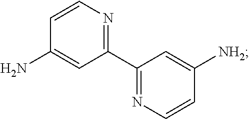 [SMILES: Nc1ccnc(-c2cc(N)ccn2)c1]
a molecular structural formula of the 2,6-diaminopyridine is: 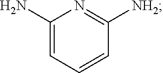
a molecular structural formula of the 2-(4-aminophenyl)-1H-benzimidazol-5-amine is: 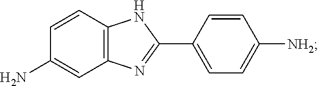 [SMILES: Nc1ccc(-c2nc3cc(N)ccc3[nH]2)cc1]
and a molecular structural formula of the 1,3-bis(3-aminophenoxy)benzene is:

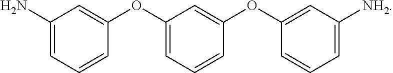 [SMILES: Nc1cccc(Oc2cccc(Oc3cccc(N)c3)c2)c1]

19. The polyimide copper clad laminate of claim 16 wherein a molar ratio of the dianhydride monomer to the diamine monomer is from 0.8 to 1.2.

20. The polyimide copper clad laminate of claim 19, wherein a molar weight of the dianhydride monomer has a range from 0.08 to 0.12 mol, and a molar weight of the diamine monomer has a range from 0.08 to 0.12 mol.
